(19) United States
(12) Patent Application Publication
(10) Pub. No.: US 2026/0340222 A1
(43) Pub. Date: Oct. 29, 2026

(54) EXPERIMENTAL PLATFORM FOR DYNAMIC FIRE HOLOGRAPHIC SIMULATION AND INTELLIGENT MEASUREMENT AND CONTROL FOR HIGH-SPEED RUNNING TRAIN IN TUNNEL, AND APPLICATION THEREOF

(71) Applicant: University of Science and Technology of China, Anhui (CN)

(72) Inventors: Fei TANG, Anhui (CN); Xinyang FAN, Anhui (CN); Longhua HU, Anhui (CN); Nannan ZHU, Anhui (CN); Yajun HUANG, Anhui (CN); Xiaolei ZHANG, Anhui (CN); Xiepeng SUN, Anhui (CN)

(73) Assignee: University of Science and Technology of China, Anhui (CN)

(21) Appl. No.: 19/273,064

(22) Filed: Jul. 17, 2025

(30) Foreign Application Priority Data
Apr. 22, 2025 (CN) 202510504400.4

(51) Int. Cl. G06F 30/20

(52) U.S. Cl. CPC G06F 30/20

(57) ABSTRACT

An experimental platform for dynamic fire holographic simulation and intelligent measurement and control for high-speed running train in tunnel and an application thereof are disclosed. The platform modularly integrates a tunnel model, a train model, a high-speed meshing drive system, an optical dynamic tracking system, a multi-modal fire holographic simulation system, a high-frequency acquisition system and a control cabinet. The tunnel model adopts a splicing structure to adapt to different experimental scenarios. The train head adopts arc structure to optimize aerodynamic performance. Inventive usage of gear and rack-sliding rod transmission mode and synchronous running technology can accurately capture dynamic shape of flames. The multi-modal fire holographic simulation system simulates fires at different fire locations in all directions. Tank chain is used for long-distance dynamic transmission of energy. The high-frequency acquisition system monitors multi-source characteristic parameters of fire in real time. The controller realizes automatic control of the experimental process.

### CROSS-REFERENCE TO RELATED APPLICATION

This application claims priority benefit of Chinese application serial no. 202510504400.4, filed on Apr. 22, 2025. The entirety of the above-mentioned patent application is hereby incorporated by reference herein and made a part of this specification.

### TECHNICAL FIELD

The present disclosure relates to a technology field of tunnel and urban rail transit safety, and more specifically to a design of an experimental platform for dynamic fire holographic simulation and intelligent measurement and control for high-speed running train in tunnel, as well as a method for processing fire characteristic parameter based on the experimental platform, which are used for research on the fire of the running train at different fire locations.

### BACKGROUND

Recent societal and urban development has driven rapid expansion of Metro systems globally. However, significant safety issues, including fire safety, raise persistent concerns that necessitate urgent research. Metro fires represent a particularly hazardous phenomenon due to its interlocking structure, dense passenger occupancy, challenging containment, and characteristic exacerbation by the complex airflow, confined space. These factors substantially amplify disaster severity.

Metro fire scenarios are categorized as train fires, station fires, or tunnel fires. When the Metro train is on fire within long-haul tunnel sections, it is difficult to stop in the tunnel and implement the on-site evacuation and rescue of people. Underground operating systems in countries other than China stipulate that that in emergency situations such as the fire, etc., the Metro train is generally not allowed to stop in the tunnel, but needs to continue driving until it enters the next station for evacuation and rescue. The current standard GB/T33668-2017 “Code for Safety Evacuation of Metro” in China stipulates that if the train is intact and has not lost power, it should continue driving to the next station for evacuation and rescue. Therefore, for the actual fire of Metro tunnel train, when the train is on fire, it is often in running state.

At present, the current research on the Metro fire and the fire smoke has achieved certain results, but there are few studies on the fire of the running train in the tunnel section in the world. Some tunnel fire experimental platforms in China can perform fire simulation under low-speed running, where it is not easy to supply the burning gas due to the complex operating conditions, and thus the experiment mostly uses the pool fire source. However, the maximum running speed of the Metro train can reach 160 km/h, and it is difficult for the pool fire source to maintain stability when the train is accelerating or decelerating. These experimental platforms cannot be used to study the fire characteristics of the high-speed running train in tunnel. At the same time, the existing running fire experimental platform captures the shape of flames based on the ground fixed camera, and it is impossible to achieve the steady shot and high-definition reproduction of the shape of flames when the train runs at high speed in the tunnel. In addition, the existing model experiment mostly studies the fire on the roof of the train, but there are fire hazard factors on the roof, the carriage, and the underbody of the train. No existing experimental platform can adequately simulate the dynamic fire scenarios of train under different fire locations and operating speeds.

### SUMMARY

To overcome the limitations identified in the prior art, the present disclosure provides an experimental platform for dynamic fire holographic simulation and intelligent measurement and control for high-speed running train in tunnel, and an application thereof. The platform establishes an efficient, controllable, and reproducible fire simulation system for comprehensive fire hazard evaluation of high-speed moving trains, thereby providing data support and scientific support for fire prevention, control, and emergency rescue operations involving high-speed running trains within long-haul tunnel sections. Simultaneously, it enables researchers to quantitatively assess fire prevention and control efficacy across diverse train fire locations (roof, carriage, underbody), thereby enhancing Metro operational safety and emergency response capabilities.

To achieve the above-mentioned purpose, the present disclosure adopts the following technical solutions.

An experimental platform for dynamic fire holographic simulation and intelligent measurement and control for high-speed running train in tunnel is provided by the present disclosure, characterized by including: a tunnel model, a train model, a high-speed meshing drive system, a multi-modal fire holographic simulation system, an optical dynamic tracking system, a high-frequency acquisition system, and a control cabinet;
a bottom plate of the tunnel model is integrated with a sliding rod and a rack, so as to provide a rail of the train model, where the train model runs on the rail through the high-speed meshing drive system;
the multi-modal fire holographic simulation system is used to simulate fire scenarios at different fire locations of the train model;
the optical dynamic tracking system runs synchronously with the train model and is used to capture a flame dynamic form of the train model in real time;
the high-frequency acquisition system is used to record parameters including temperature, a heat flux, and a gas concentration in real time; and
the control cabinet is used to control running of the train model and the optical dynamic tracking system, fire extent of the multi-modal fire holographic simulation system, shooting duration of the optical dynamic tracking system, and start and stop of the high-frequency acquisition system.

The experimental platform for dynamic fire holographic simulation and intelligent measurement and control for high-speed running train in tunnel is provided by the present disclosure, further characterized by the tunnel model and the train model are arranged as follows:
the tunnel model is fixed on a tunnel model bracket, where a top plate of the tunnel model bracket serves as the bottom plate of the tunnel model, the tunnel model is spliced by a plurality of standard section models, any one of the plurality of standard section models is a door-shaped model composed of three aluminum alloy plates, a high-temperature resistant fireproof board is provided inside the aluminum alloy plates, and a high-temperature resistant glass is provided on side of any one of the aluminum alloy plates;
a slot is installed on an outer side of the top plate of the tunnel model bracket, where two sliding rods are fixed at a center of the top plate, the rack is laid on an inner side of the top plate, two tunnel model stoppers are installed at both ends of the top plate of the tunnel model bracket, and the top plate of the tunnel model bracket is provided with a first locator on a running start side of the train model;
the train model is divided into a straight segment body and an arc segment head, where the train model is spliced by the aluminum alloy plates, the train model is fixed on a support plate of the train model by two support rods, a bottom of the support plate of the train model is installed with a first sliding bearing, the first sliding bearing is arranged on two sliding rods on the top plate of the tunnel model bracket, and the arc segment head of the train model is provided with an identification light powered by battery.

Further, the high-speed meshing drive system includes: a first gear, a first drive motor, a first motor support frame, a first connecting plate, a first power line, a first control line, and a first tank chain;
the first motor support frame is assembled by the three aluminum alloy plates, where the first drive motor is arranged on an inner bottom surface of the first motor support frame, the first drive motor is connected to the first gear through a gear shaft, and the first gear is meshed with a rack on the top plate of the tunnel model bracket;
a bottom of a bottom surface of the first motor support frame is connected to a second sliding bearing, where the second sliding bearing is arranged on the two sliding rods of the top plate of the tunnel model bracket and is located behind a running direction of the first sliding bearing;
a side of the first motor support frame with same direction as a running direction of the train model is connected to the support plate of the train model through a first connecting plate, whereby the first drive motor drives the train model to run in a sliding way on the two sliding rods through the first sliding bearing and the second sliding bearing; and
a side of the first motor support frame with opposite direction to a running direction of the train model is connected to the first tank chain, where the first tank chain is arranged in the slot of the top plate of the tunnel model bracket, and the first power line and first control line are arranged inside the first tank chain and connected to the control cabinet, so as to provide power and control signal for the first drive motor.

Furthermore, the multi-modal fire holographic simulation system includes: a fire head, a solenoid valve, a solenoid valve power cord, a flow meter, a first gas supply pipeline, a second gas supply pipeline, a third gas supply pipeline, a gas cylinder, a high-voltage arc igniter, and a temperature probe;
the fire head includes: an inner gas supply component and an outer sleeve, where the inner gas supply component includes: a gas supply head and a pneumatic joint;
the gas supply head is provided with a gas supply passage with air holes therein, where both ends of the gas supply head are respectively connected with the pneumatic joint and the outer sleeve in a threaded way, and there is an annular gap between the gas supply head and the outer sleeve for outer gas supply;
the fire head is fixed on the train model through a threaded connection, where the high-voltage arc igniter and the temperature probe are arranged directly above the fire head, the gas cylinder is connected to the third gas supply pipeline through a pressure reducing valve, the third gas supply pipeline is connected to an inlet of the flow meter, an outlet of the flow meter is connected to the second gas supply pipeline, the second gas supply pipeline is arranged inside the first tank chain and connected to the solenoid valve, the solenoid valve is connected to the first gas supply pipeline, and the first gas supply pipeline is connected to the pneumatic joint of the fire head;
the flow meter controls a power of a fire source by adjusting a mass flow of gas being introduced.

Furthermore, the optical dynamic tracking system includes: an optical dynamic tracking system bracket, a motion camera, a first camera support plate, a second camera support plate, a synchronous tracking power system, two optical dynamic tracking system stoppers, and a second locator;
a slot is installed on an outer side of a top plate of the optical dynamic tracking system bracket, where two sliding rods are fixed at a center of the top plate, a rack is laid on an inner side of the top plate, two optical dynamic tracking system stoppers are installed at both ends of the top plate of the optical dynamic tracking system bracket, and the top plate of the optical dynamic tracking system bracket is provided with a second locator on a running start side of the motion camera;
the motion camera is fixed on the first camera support plate, where the first camera support plate is connected to the second camera support plate through two threaded connecting rods, a third sliding bearing is installed at a bottom of the second camera support plate, and the third sliding bearing is arranged on the two sliding rods of the top plate of the optical dynamic tracking system bracket.

Furthermore, the synchronous tracking power system includes: a second gear, a second drive motor, a second motor support frame, a second connecting plate, a second power line, a second control line, and a second tank chain;
the second motor support frame is an aluminum alloy flat plate, where the second drive motor is arranged on an inner bottom surface of the second motor support frame, the second drive motor is connected to the second gear through a gear shaft, and the second gear is meshed with a rack on the optical dynamic tracking system bracket;
a bottom of a bottom surface of the second motor support frame is connected to a fourth sliding bearing, and the fourth sliding bearing is arranged on the two sliding rods of the top plate of the optical dynamic tracking system bracket and is located behind a running direction of the third sliding bearing;
a side of the second motor support frame with same direction as a running direction of the motion camera is connected to the second camera support plate of the motion camera through the second connecting plate, whereby the second drive motor drives the motion camera to run in a sliding way on the two sliding rods through the third sliding bearing and the fourth sliding bearing; and
a side of the second motor support frame with opposite direction to a running direction of the motion camera is connected to the second tank chain, where the second tank chain is arranged in the slot of the top plate of the optical dynamic tracking system bracket, and the second power line and the second control line are arranged inside the second tank chain and connected to the control cabinet, so as to provide power and control signal for the second drive motor.

Furthermore, the high-frequency acquisition system includes: a thermocouple, a heat flux meter, a high-speed acquisition device, and water-cooled device, where the water-cooled device includes: a water pump, a water tank, and a water pump power line;
the thermocouple and the heat flux meter are arranged on a top plate and a bottom plate of the train model, where a wiring of the thermocouple and the heat flux meter is connected to the high-speed acquisition device, the water pump is fixed to a bottom of the water tank, a water inlet pipe of the heat flux meter is connected to a water outlet pipe of the water pump, a water outlet pipe of the heat flux meter is inserted into the water tank, the second power line provides a power for the water pump, and the high-speed acquisition device is powered by using a battery.

A control system based on the experimental platform for dynamic fire holographic simulation and intelligent measurement and control for high-speed running train in tunnel is provided by the present disclosure, characterized by carrying out according to following steps:
step 1, controlling, by the control cabinet, the first drive motor to drive the train model to move toward a direction of the first locator in a low-speed mode, and controlling the second drive motor to drive the motion camera to move toward a direction of the second locator in the low-speed mode;
when the train model reaches the first locator, and a Hall sensor in the first locator detects a change in a magnetic field, an encoder pulse count value of the first drive motor is cleared, and a position of the train model when it reaches the first locator is set to an initial position x_{0,train},
when the motion camera reaches the second locator, and a Hall sensor in the second locator detects a change in a magnetic field, an encoder pulse count value of the second drive motor is cleared, and a position of the motion camera when it reaches the second locator is set to an initial position x_{0,camera};
step 2, setting experimental parameters, including: a length of the tunnel model Lₜᵤₙₙₑₗ, a length of the optical dynamic tracking system bracket L_{trace}, the mass flow of gas in the flow meter mₛₑₜ, a running speed of the train model v_{set,train}, a running speed of the motion camera v_{set,camera}, a running displacement of the train model x_{set,train}, and a running displacement of the motion camera x_{set,camera},
step 3, starting, by the control cabinet 20, the solenoid valve 10, starting the flow meter 12 to supply gas according to a set target mass flow mₛₑₜ, and at the same time, triggering the high-voltage arc igniter to ignite the fire source, and synchronously starting the temperature probe to monitor a state of the fire source in real time;
step 4, collecting, by the flow meter 12, a mass flow mᵣₑₐₗ(t) at time t in the gas supply pipeline, and calculating a mass flow fluctuation rate e(t)=mₛₑₜ−mᵣₑₐₗ(t) at time t, where if e(t) is less than a set flow threshold, then a step 5 is executed, otherwise, a Proportional Integral Derivative (PID) control algorithm is used to adjust the mᵣₑₐₗ(t), and a flow control value u(t) at time t is obtained by using formula (a), so as to control the flow meter 12 to adjust a mass flow of its own gas being introduced, whereby e(t) is less than the set flow threshold:

$$u ( t ) = {K}_{p} e ( t ) + {K}_{i} {\int }_{0}^{t} e ( τ ) dt + {K}_{d} \frac{de ( t )}{dt} \qquad ( a )$$

where, in formula (a), Kₚ is a proportional coefficient, Kᵢ is an integral coefficient, and K_{d} is a differential coefficient;
step 5, triggering, by the control cabinet, the high-voltage arc igniter to ignite the fire source, and synchronously starting the temperature probe to monitor the state of the fire source in real time, and starting the high-speed acquisition device to collect data from the thermocouple and the heat flux meter;
step 6, controlling the train model and the motion camera to run synchronously;
step 7, closing, by the control cabinet, the solenoid valve, returning the mass flow in the flow meter to be zero, and closing the temperature probe and the high-speed acquisition device and the water-cooled device, when Nₜᵣₐᵢₙ(t)=0 and N_{camera}(t)=0, which means that braking is completed.

The control system based on the experimental platform for dynamic fire holographic simulation and intelligent measurement and control for high-speed running train in tunnel is provided by the present disclosure, characterized by the step 6 further including:
step 6.1, obtaining a control frequency fₜᵣₐᵢₙ of the first drive motor according to formula (b) to control the train model to run at the running speed v_{set,train}.

$${f}_{train} = \frac{{v}_{set , train} \cdot {N}_{p}}{π mZ} \qquad ( b )$$

where, in formula (b), m is a module of a gear in the train model, Z is a teeth number of the gear in the train model, and Nₚ is a number of pole pairs of the first drive motor;
step 6.2, using, by the control cabinet, a high-precision encoder built in the first drive motor to collect a pulse signal Nₜᵣₐᵢₙ(t) of a rotation angle of the first drive motor at time t, so as to use formula (c) to obtain a running speed v_{real,train}(t) of the train model at time t:

$${v}_{real , train} ( t ) = \frac{N ( t ) \cdot Δθ \cdot π mZ}{60 {N}_{p}} \qquad ( c )$$

where, in formula (c), Δθ is a fixed angle of a rotation of a motor gear corresponding to a single pulse;
step 6.3, calculating, by the control cabinet, a running speed error v_{e,train}(t)=v_{set,train}−v_{real,train}(t) of the train model at time t;
step 6.4, if the v_{e,train}(t) is less than a set speed threshold, then the step 5 is executed, otherwise, the PID control algorithm is used to adjust the v_{e,train}(t) to obtain a control frequency f_{output,train}(t) of the first drive motor at time t, so as to control the running speed v_{e,train}(t) of the train model at time t to be less than the set speed threshold;
step 6.5, if L_{trace}<Lₜᵤₙₙₑₗ, calculating, by the control cabinet, a delayed start time t_{delay}=(Lₜᵤₙₙₑₗ−L_{trace})/vₜᵣₐᵢₙ of the motion camera, otherwise, t_{delay}=0 is set to start the motion camera according to the t_{delay},
step 6.6, calculating, by the control cabinet, a running speed v_{e,camera}(t)=v_{set,camera}−v_{real,camera}(t) of the motion camera at time t, where if v_{e,camera}(t) is less than a set speed threshold, then step 6.7 is executed, otherwise, adjusting v_{e,camera}(t) according to the PID control algorithm to control v_{e,camera}(t) to be less than the set speed threshold;
step 6.7, calculating, by the control cabinet, an actual displacement xₜᵣₐᵢₙ₍ₜ₎ of the train model at time t and an actual displacement x_{camera}(t) of the motion camera at time t by using formula (d) and formula (e) respectively:

$${x}_{train} ( t ) = {N}_{train} ( t ) \cdot {x}_{w} \qquad ( d )$$

$${x}_{camera} ( t ) = {N}_{camera} ( t ) \cdot {x}_{w} \qquad ( e )$$

where, in formula (d) and formula (e), x_{w} represents a single pulse displacement, x_{w}=πmZ/Nₚ, and N_{camera}(t) is a pulse signal of a rotation angle of the second drive motor at time
step 6.8, when x_{camera}(t)≥x_{set,camera}, controlling, by the control cabinet, the first drive motor to apply a reverse torque to perform deceleration braking on the train model, otherwise, t+1 is assigned to t, and the step 6.2 is returned to execute sequentially;
when x x_{camera}(t)>x_{set,camera}, controlling, by the control cabinet, the second drive motor to apply a reverse torque to perform deceleration braking on the motion camera, otherwise, t+1 is assigned to t, and the step 6.6 is returned to execute sequentially.

A fire characteristic parameter processing method based on the control system is provided by the present disclosure, characterized by carrying out according to following steps:
step I, obtaining a flame video sequence shot by the motion camera after braking is completed, on which stability processing is performed, then converting it from a Red Green Blue (RGB) color space to a grayscale space, so as to use a threshold segmentation algorithm to binarize each frame of a flame image in the grayscale flame video sequence to obtain a binary flame video sequence;
step II, overlaying the binary flame video sequence frame by frame, and counting a frequency of flame occurrence at each pixel point, so as to construct a flame probability density matrix

$$P ( x , y ) = \frac{1}{N} {\sum }_{t = 1}^{N} {M}_{t} ( x , y )$$

at the pixel point (x, y), where Mₜ(x, y) is a binary value at the pixel point (x, y) in a t^{th} frame flame image, and Nis a total number of frames;
step III, mapping, according to a calibration parameter of the motion camera, the pixel point (x, y) to the pixel point (Xᵣₑₐₗ,Yᵣₑₐₗ) in an actual physical coordinate system: Xᵣₑₐₗ=α·x·ρ, Yᵣₑₐₗ=α·y·ρ, SO as to construct a flame probability density matrix

$$P ( {X}_{real} , {Y}_{real} ) = \frac{1}{N} {\sum }_{t = 1}^{N} {M}_{t} ( {X}_{real} , {Y}_{real} )$$

at the pixel point (Xᵣₑₐₗ,Yᵣₑₐₗ) in an actual physical coordinate system, where ρ is a pixel resolution of the motion camera, and a is a spatial scale factor of the motion camera;
step Iv, extracting a flame boundary based on P (Xᵣₑₐₗ,Yᵣₑₐₗ), and obtaining flame scale data, which includes a flame length L_{f}, and a flame height H_{f},
step V: using formula (f) and formula (g) to establish a dimensionless flame length model and a dimensionless flame height model respectively:

$$\frac{{L}_{f}}{D} = {f}_{1} ( \text{?} , {V}^{*} ) = {f}_{1} ( \frac{{m}_{set} Δ H}{{ρ}_{a} {c}_{p} {T}_{a} {g}^{1 / 2} {D}^{5 / 2}} , \frac{{v}_{set , train}}{\sqrt{gD}} ) \qquad ( f )$$

$$\frac{{H}_{f}}{D} = {f}_{2} ( \text{?} , {V}^{*} ) = {f}_{2} ( \frac{{m}_{set} Δ H}{{ρ}_{a} {c}_{p} {T}_{a} {g}^{1 / 2} {D}^{5 / 2}} , \frac{{v}_{set , train}}{\sqrt{gD}} ) \qquad ( g )$$

where, in formula (f) and formula (g), Q^{&} is a dimensionless fire source heat release rate, V* is a dimensionless train model running speed, D is a diameter of the fire head, ΔH is a calorific value of the fire source fuel, ρₐ is an initial environment density, cₚ is a constant pressure specific heat capacity, Tₐ is an initial environment temperature, g is a gravitational acceleration, f₁ is a flame length relationship, and f₂ is a flame height relationship;
step VI, drawing a time series graph and calculating an average value of a stable segment based on data collected by the thermocouple and the heat flux meter on the top plate and the bottom plate of the train model, so as to use an average value of a thermocouple stable segment as a temperature value t_{f} of the train model, and use a product of an average value of a heat flux meter stable segment and a correction coefficient as a heat flux value q_{f} of the train model;
step VII, performing normalization processing on a temperature value t_{f} and a heat flux value q_{f} according to formula (h) and formula (i) respectively to obtain a normalized temperature value t*_{f} and a normalized heat flux value q*_{f}:

$${t}_{f}^{⋆} = \frac{Δ {t}_{f}}{Δ {t}_{peak}} \qquad ( h )$$

$${q}_{f}^{*} = \frac{{q}_{f} {D}^{2}}{{m}_{set} Δ H} \qquad ( i )$$

where, in formula (h) and formula (i), Δt_{f} represents a temperature rise on the top plate and the bottom plate of the train model, Δt_{f}=t_{f}−Tₐ, Δtₚₑₐₖ represents a temperature rise peak on the top plate and the bottom plate of the train model, Δtₚₑₐₖ=tₚₑₐₖ−Tₐ, and tₚₑₐₖ is a temperature peak on the top plate and the bottom plate of the train model;
step VIII, establishing a temperature rise peak model on the top plate and the bottom plate of the train model according to formula (j):

$$\frac{Δ {t}_{peak}}{{T}_{a}} = {f}_{3} ( \frac{{v}_{set , train}}{\sqrt{gD}} ) \qquad ( j )$$

where, in formula (j), f₃ is a temperature rise peak relationship;
establishing a temperature distribution prediction model on the top plate and the bottom plate of the train model according to formula (k):

$${t}_{f}^{*} = \frac{Δ {t}_{f}}{Δ {t}_{peak}} = {f}_{4} ( \frac{x}{X} ) \qquad ( k )$$

where, in formula (k), f₄ is a temperature distribution relationship, x is a distance between a thermocouple position and the temperature rise peak on the top plate and the bottom plate of the train model, X is a characteristic scale of the fire source, and

$$X = {( \frac{{m}_{set} Δ H}{{ρ}_{a} {c}_{ρ} {T}_{a} {g}^{1 / 2}} )}^{2 / 5} ;$$

step IX, obtaining a heat flux distribution characterization model on a roof of a running train on fire according to formula (1):

$${q}_{f}^{*} = \frac{{q}_{f} {D}^{2}}{{m}_{set} Δ H} = {f}_{5} ( \frac{{x}^{′}}{D} , \frac{{v}_{set , train}}{\sqrt{gD}} ) \qquad ( l )$$

where, in formula (1), f₅ is a heat flux distribution relationship, x′ is a distance between the heat flux meter and a center of the fire head on the train model.

### BRIEF DESCRIPTION OF DRAWINGS

FIG. 1 is a schematic diagram of an experimental platform for dynamic fire holographic simulation and intelligent measurement and control for high-speed running train in tunnel.

FIG. 2 is a structural schematic diagram of a tunnel model.

FIG. 3 is a top view of a layout of a bottom plate of the tunnel model.

FIG. 4A and FIG. 4B are front view of a fire head and top view of the fire head.

FIG. 5 is a schematic diagram of a high-frequency acquisition system.

FIG. 6 is a control system based on the experimental platform for dynamic fire holographic simulation and intelligent measurement and control for high-speed running train in tunnel.

FIG. 7 is a step 6 of the control system based on the experimental platform for dynamic fire holographic simulation and intelligent measurement and control for high-speed running train in tunnel;

Reference numbers in the figures: 1. Tunnel model; 2. Train model; 3. Support plate of train model; 4. Identification light; 5. Drive motor; 6. First motor support frame; 7. First power line; 8. First control line; 9. First tank chain; 10. Solenoid valve; 11. Gas cylinder; 12. Flow meter; 13. Fire head; 14. First gas supply pipeline; 15. Second gas supply pipeline; 16. Third gas supply pipeline; 17. Second camera support plate; 18. Motion camera; 19. First camera support plate; 20. Control cabinet; 21. First connecting plate; 22. First gear; 23. Sliding rod; 24. Slot; 25. Rack; 26. High-speed acquisition device; 27. Water pump; 28. Water tank; 29. Tunnel model stopper; 30. Heat flux meter; 31. Thermocouple; 32. Aluminum alloy plate; 33. High-temperature resistant glass; 34. Tunnel model bracket; 35. Gas supply head; 36. Outer sleeve; 37. Gas supply head; 38. Pneumatic joint; 39. Gas supply passage; 40. Circular air hole; 41. Optical dynamic tracking system stopper.

### DESCRIPTION OF EMBODIMENTS

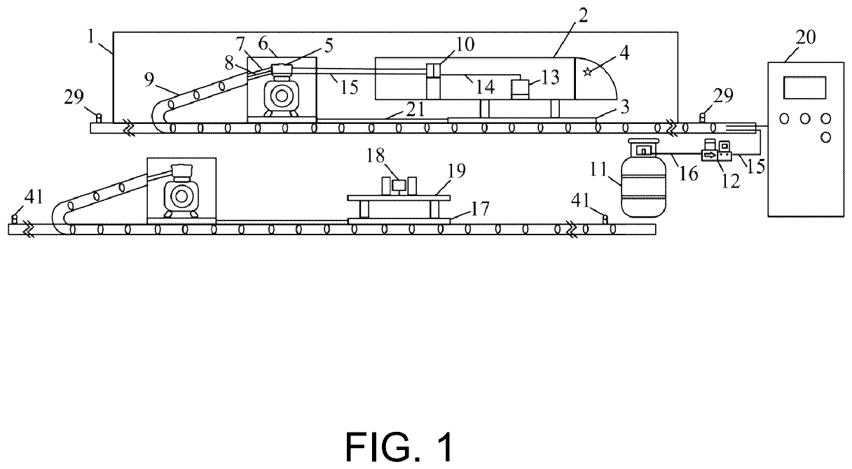

In the present embodiment, as shown in FIG. 1, in order to make up for the fact that the experimental platform is still insufficient for simulating the fire of high-speed running train in tunnel within long-haul tunnel sections, an efficient, controllable and reproducible experimental platform for dynamic fire holographic simulation and intelligent measurement and control for high-speed running train in tunnel is designed to study the fire prevention and control of different locations of the running train. Specifically, the platform includes: a tunnel model 1, a train model 2, a high-speed meshing drive system, a multi-modal fire holographic simulation system, an optical dynamic tracking system, a high-frequency acquisition system, and a control cabinet 20.

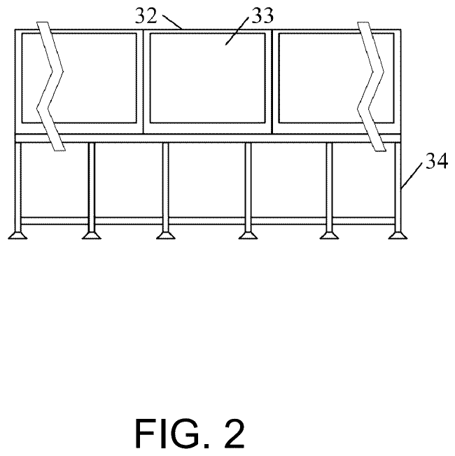

As shown in FIG. 2, the tunnel model 1 is fixed on a tunnel model bracket 34. A top plate of the tunnel model bracket 34 serves as a bottom plate of the tunnel model. The tunnel model 1 is spliced by a plurality of standard section models, which supports a modular expansion of a tunnel model length within a required range to meet simulation requirements of tunnels in different intervals. Any one of the plurality of standard section models is a door-shaped model composed of three aluminum alloy plates 32. A high-temperature resistant fireproof board is provided inside the aluminum alloy plates 32. A high-temperature resistant glass 33 is provided on side of any one of the aluminum alloy plates 32.

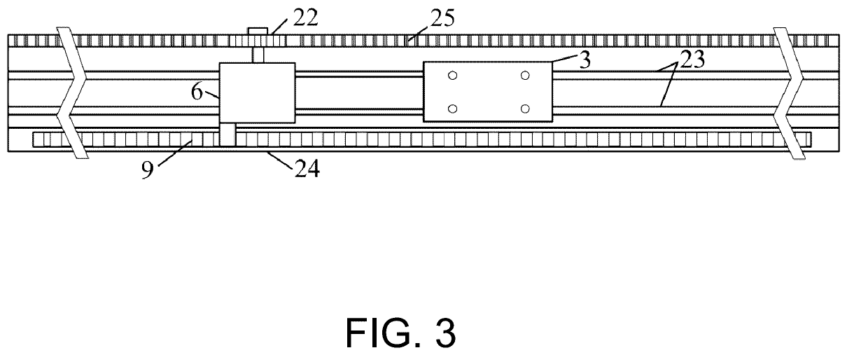

As shown in FIG. 3, a slot 24 is installed on an outer side of the top plate of the tunnel model bracket 34. Two sliding rods 23 are fixed at a center of the top plate. A rack 25 is laid on an inner side of the top plate. Two tunnel model stoppers 29 are installed at both ends of the top plate of the tunnel model bracket 34. The top plate of the tunnel model bracket 34 is provided with a first locator on a running start side of the train model 2.

The train model 2 is divided into a straight segment body and an arc segment head. The arc segment head is used for stabilizing an airflow. The train model 2 is spliced by the aluminum alloy plates 32. The train model 2 is fixed on a support plate 3 of the train model by two support rods. A bottom of the support plate 3 of the train model is installed with a first sliding bearing. The first sliding bearing is arranged on two sliding rods 23 on the top plate of the tunnel model bracket 34. The arc segment head of the train model is provided with an identification light 4 powered by battery.

The high-speed meshing drive system includes: a first gear 22, a first drive motor 5, a first motor support frame 6, a first connecting plate 21, a first power line 7, a first control line 8, and a first tank chain 9.

The first motor support frame 6 is assembled by the three aluminum alloy plates 32. The first drive motor 5 is arranged on the inner bottom surface of the first motor support frame 6. The first drive motor 5 is connected to the first gear 22 through the gear shaft. The first gear 22 is meshed with the rack 25 on the top plate of the tunnel model bracket.

A bottom of a bottom surface of the first motor support frame 6 is connected to a second sliding bearing. The second sliding bearing is arranged on the two sliding rods 23 of the top plate of the tunnel model bracket 34 and is located behind a running direction of the first sliding bearing.

A side of the first motor support frame 6 with same direction as a running direction of the train model 2 is connected to the support plate 3 of the train model 2 through the first connecting plate 21, whereby the first drive motor 5 drives the train model 2 to run in a sliding way on the two sliding rods 23 through the first sliding bearing and the second sliding bearing.

A side of the first motor support frame 6 with opposite direction to the running direction of the train model 2 is connected to the first tank chain 9. The first tank chain 9 is arranged in the slot 24 of the top plate of the tunnel model bracket 34. The first power line 7 and first control line 8 are arranged inside the first tank chain 9 and connected to the control cabinet 20, so as to provide power and control signal for the first drive motor 5.

The multi-modal fire holographic simulation system includes: a fire head 13, a solenoid valve 10, a solenoid valve power cord, a flow meter 12, a first gas supply pipeline 14, a second gas supply pipeline 15, a third gas supply pipeline 16, a gas cylinder 11, a high-voltage arc igniter, and a temperature probe.

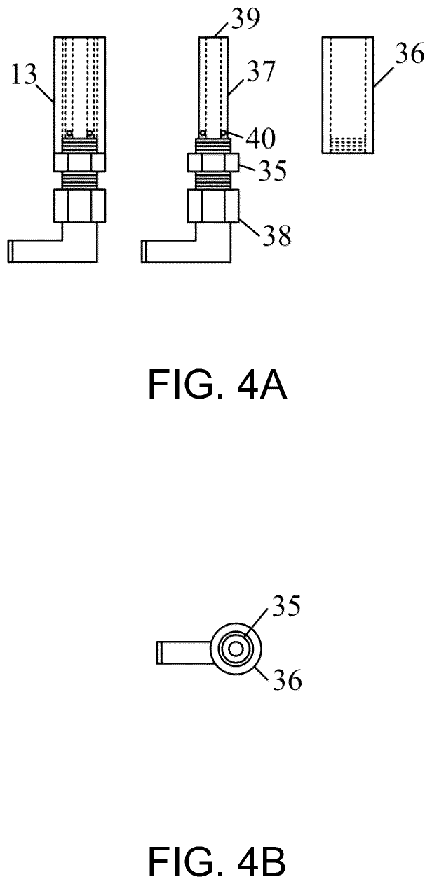

As shown in FIG. 4A and FIG. 4B, the fire head 13 includes: an inner gas supply component 35 and an outer sleeve 36. The inner gas supply component 35 includes: a gas supply head 37 and a pneumatic joint 38.

The gas supply head 37 is provided with a gas supply passage 39 with air holes 40 therein. Both ends of the gas supply head 37 are respectively connected with the pneumatic joint 38 and the outer sleeve 36 in a threaded way, and there is an annular gap between the gas supply head 37 and the outer sleeve 36 for outer gas supply. Because the gas supply passage 39 is designed inside a fire head and four circular air holes 40 are arranged in middle and lower parts, A fuel gas flows through the gas supply passage 39 and at the same time flows through the circular air holes 40 to the annular gap between the gas supply head 37 and the outer sleeve 36, under conditions of low power and high running speed, A flame in the annular gap has a blocking effect on an inner flame of the gas supply passage 39, which prevents a high-speed airflow from directly blowing out the flame, thereby facilitating in-depth research on a influence of a running speed.

The fire head 13 is fixed on the train model 2 through a threaded connection. The high-voltage arc igniter and the temperature probe are arranged directly above the fire head. The gas cylinder 11 is connected to a third gas supply pipeline 16 through a pressure reducing valve. The third gas supply pipeline 16 is connected to an inlet of the flow meter 12. An outlet of the flow meter 12 is connected to the second gas supply pipeline 15. The second gas supply pipeline 15 is arranged inside the first tank chain 9 and connected to the solenoid valve 10. The solenoid valve 10 is connected to the first gas supply pipeline 14. The first gas supply pipeline 14 is connected to a pneumatic joint of the fire head 13.

The flow meter 12 controls a power of a fire source by adjusting a mass flow of gas being introduced.

The optical dynamic tracking system includes: an optical dynamic tracking system bracket, a motion camera 18, a first camera support plate 19, a second camera support plate 17, a synchronous tracking power system, two optical dynamic tracking system stoppers, and a second locator.

A slot is installed on an outer side of a top plate of the optical dynamic tracking system bracket. Two sliding rods are fixed at a center of the top plate. A rack is laid on an inner side of the top plate. Two optical dynamic tracking system stoppers are installed at both ends of the top plate of the optical dynamic tracking system bracket. The top plate of the optical dynamic tracking system bracket is provided with the second locator on a running start side of the motion camera 18. A length of the optical dynamic tracking system bracket can be shorter than that of the tunnel model bracket, since some experiments only need to shoot a fire phenomenon at a shorter distance. At the same time, use and consumption of experimental platform construction materials can be reduced. A delayed start time of the motion camera 18 is set by the control cabinet 20, and dynamic tracking shooting of the motion camera 18 under different bracket lengths can be realized.

The motion camera 18 is fixed on the first camera support plate 19. The first camera support plate 19 is connected to the second camera support plate 17 through two threaded connecting rods. A third sliding bearing is installed at a bottom of the second camera support plate 17. The third sliding bearing is arranged on two sliding rods of the top plate of the optical dynamic tracking system bracket.

The synchronous tracking power system includes: a second gear, a second drive motor, a second motor support frame, a second connecting plate, a second power line, a second control line, and a second tank chain.

The second motor support frame is an aluminum alloy flat plate. The second drive motor is arranged on an inner bottom surface of the second motor support frame, and the second drive motor is connected to the second gear through a gear shaft. The second gear is meshed with the rack on the optical dynamic tracking system bracket.

A bottom of a bottom surface of the second motor support frame is connected to a fourth sliding bearing. The fourth sliding bearing is arranged on the two sliding rods of the top plate of the optical dynamic tracking system bracket and is located behind a running direction of the third sliding bearing.

A side of the second motor support frame with same direction as a running direction of the motion camera 18 is connected to the second camera support plate 17 of the motion camera 18 through the second connecting plate, whereby the second drive motor drives the motion camera 18 to run in a sliding way on the two sliding rods through the third sliding bearing and the fourth sliding bearing.

A side of the second motor support frame with opposite direction to the running direction of the motion camera 18 is connected to the second tank chain. The second tank chain is arranged in a slot of the top plate of the optical dynamic tracking system bracket. The second power line and the second control line are arranged inside the second tank chain and connected to the control cabinet, so as to provide power and control signal for the second drive motor.

A braking of the high-speed meshing drive system and the optical dynamic tracking system is controlled by a built-in program of the console. After the train model 2 and the motion camera 18 run at a set distance, they brake and stop. When the program is failed or invalid, the train model 2 and the motion camera 18 will brake and stop again after passing through the tunnel model stopper 29 and the optical dynamic tracking system stopper 41, which prevents them from rushing out of an experimental area, where the tunnel model stopper 29 and the optical dynamic tracking system stopper 41 play a redundant protection role.

The high-frequency acquisition system includes: a thermocouple 31, a heat flux meter 30, a high-speed acquisition device 26, and water-cooled device. The water-cooled device includes:

a water pump 27, a water tank 28, and a water pump power line.

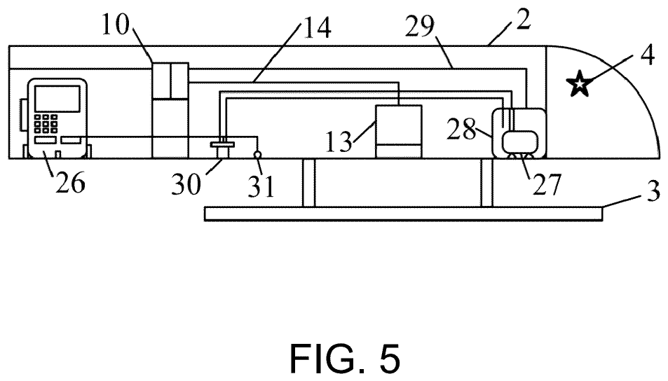

As shown in FIG. 5, the thermocouple 31 and the heat flux meter 30 are arranged on a top plate and a bottom plate of the train model 2. A wiring of the thermocouple 31 and the heat flux meter 30 is connected to the high-speed acquisition device 26. The water pump 27 is fixed to a bottom of the water tank 28. A water inlet pipe of the heat flux meter 30 is connected to a water outlet pipe of the water pump 27. A water outlet pipe of the heat flux meter 30 is inserted into the water tank 28. The second power line provides a power for the water pump 27. The high-speed acquisition device 26 is powered by using a battery. The water-cooled device circulates water to cool the heat flux meter 30 to prevent heat flux meter 30 from overheating and failure.

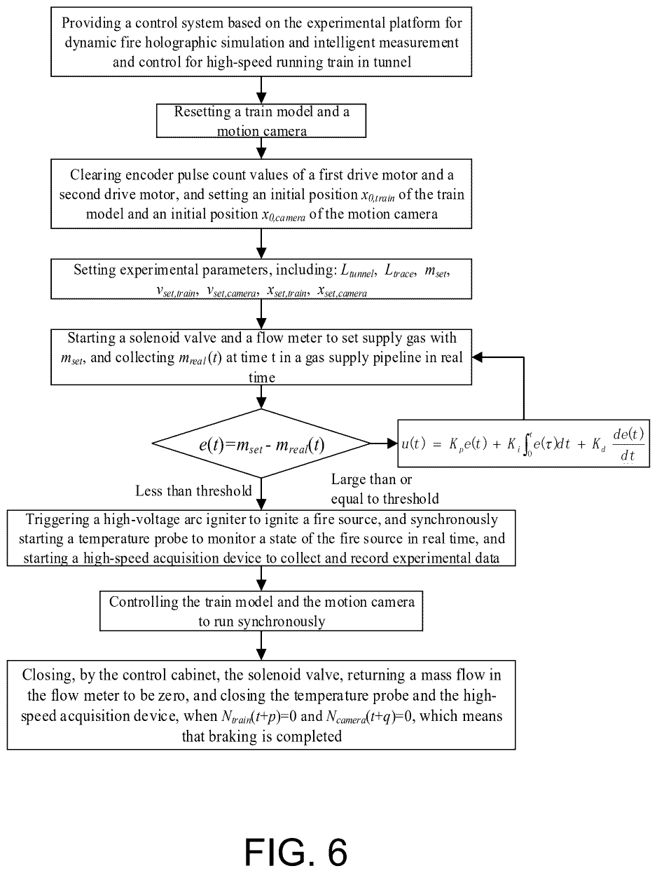

In the present embodiment, as shown in FIG. 6, a control system based on the experimental platform for dynamic fire holographic simulation and intelligent measurement and control for high-speed running train in tunnel is provided, characterized by carrying out according to following steps:

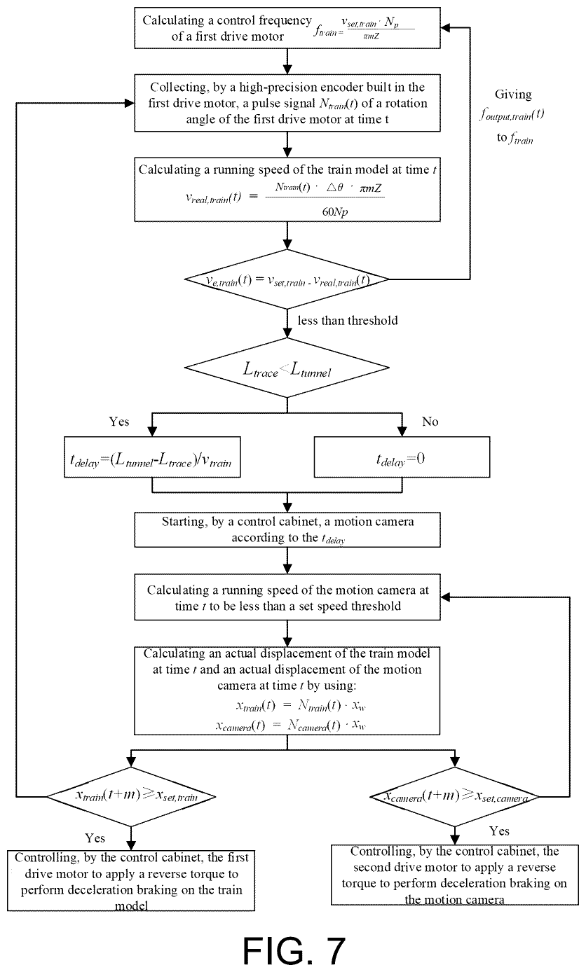

step 1, controlling, by the control cabinet 20, the first drive motor 5 to drive the train model 2 to move toward a direction of the first locator in a low-speed mode, and controlling the second drive motor to drive the motion camera 18 to move toward a direction of the second locator in the low-speed mode;
when the train model 2 reaches the first locator, and a Hall sensor in the first locator detects a change in a magnetic field, an encoder pulse count value of the first drive motor 5 is cleared, and a position of the train model 2 when it reaches the first locator is set to an initial position x_{0,train}, when the motion camera 18 reaches the second locator, and a Hall sensor in the second locator detects a change in a magnetic field, an encoder pulse count value of the second drive motor is cleared, and a position of the motion camera 18 when it reaches the second locator is set to an initial position x_{0,camera};
step 2, setting experimental parameters, including: a length of the tunnel model 1 Lₜᵤₙₙₑₗ, a length of the optical dynamic tracking system bracket L_{trace}, the mass flow of gas in the flow meter 12 mₛₑₜ, a running speed of the train model 2 v_{set,train}, a running speed of the motion camera 18 v_{set,camera}, a running displacement of the train model 2 x_{set,train}, and a running displacement of the motion camera 18 x_{set,camera},
step 3, starting, by the control cabinet 20, the solenoid valve 10, starting the flow meter 12 to supply gas according to a set target mass flow mₛₑₜ, and at the same time, triggering the high-voltage arc igniter to ignite the fire source, and synchronously starting the temperature probe to monitor a state of the fire source in real time;
step 4, collecting, by the flow meter 12, a mass flow mᵣₑₐₗ(t) at time t in the gas supply pipeline, and calculating a mass flow fluctuation rate e(t)=mₛₑₜ−mᵣₑₐₗ(t) at time t, where if e(t) is less than a set flow threshold, then a step 5 is executed, otherwise, a PID control algorithm is used to adjust the mᵣₑₐₗ(t), and a flow control value u(t) at time t is obtained by using formula (a), so as to control the flow meter 12 to adjust a mass flow of its own gas being introduced, whereby e(t) is less than the set flow threshold:

$$u ( t ) = {K}_{p} e ( t ) + {K}_{i} {\int }_{0}^{t} e ( τ ) dt + {K}_{d} \frac{de ( t )}{dt} \qquad ( a )$$

where, in formula (a), Kₚ is a proportional coefficient, Kᵢ is an integral coefficient, and K_{d} is a differential coefficient;
step 5, starting, by the control cabinet 20, the high-speed acquisition device to collect data from the thermocouple 31 and the heat flux meter 30;
step 6, as shown in FIG. 7, controlling the train model 2 and the motion camera 18 to run synchronously;
step 6.1, obtaining a control frequency fₜᵣₐᵢₙ of the first drive motor 5 according to formula (b) to control the train model 2 to run at the running speed v_{set,train}:

$${f}_{train} = \frac{{v}_{set , train} \cdot {N}_{p}}{π mZ} \qquad ( b )$$

where, in formula (b), m is a module of a gear in the train model 1, Z is a teeth number of the gear in the train model 1, and Nₚ is a number of pole pairs of the first drive motor 5;
step 6.2, using, by the control cabinet 20, a high-precision encoder built in the first drive motor 5 to collect a pulse signal Nₜᵣₐᵢₙ(t) of a rotation angle of the first drive motor 5 at time t, so as to use formula (c) to obtain a running speed v_{real,train}(t) of the train model 2 at time t:

$${v}_{real , train} ( t ) = \frac{N ( t ) \cdot Δθ \cdot π mZ}{60 {N}_{p}} \qquad ( c )$$

where, in formula (c), Δθ is a fixed angle of a rotation of a motor gear corresponding to a single pulse;
step 6.3, calculating, by the control cabinet 20, a running speed error v_{e,train}(t)=v_{set,train}−v_{real,train}(t) of the train model 2 at time t;
step 6.4, if the v_{e,train}(t) is less than a set speed threshold, then the step 5 is executed, otherwise, the PID control algorithm is used to adjust the v_{e,train}(t) to obtain a control frequency f_{output,train}(t) of the first drive motor 5 at time t, so as to control the running speed v_{e,train}(t) of the train model 2 at time t to be less than the set speed threshold;
step 6.5, if L_{trace}<Lₜᵤₙₙₑₗ, calculating, by the control cabinet 20, a delayed start time t_{delay}=(Lₜᵤₙₙₑₗ−L_{trace})/vₜᵣₐᵢₙ of the motion camera 18, otherwise, t_{delay}=0 is set to start the motion camera 18 according to the t_{delay},
step 6.6, calculating, by the control cabinet 20, a running speed v_{e,camera}(t)=v_{set,camera}−v_{real,camera}(t) of the motion camera 18 at time t, where if v_{e,camera}(t) is less than a set speed threshold, then step 6.7 is executed, otherwise, adjusting v_{e,camera}(t) according to the PID control algorithm to control v_{e,camera}(t) to be less than the set speed threshold;
step 6.7, calculating, by the control cabinet 20, an actual displacement xₜᵣₐᵢₙ(t) of the train model 2 at time t and an actual displacement x_{camera}(t) of the motion camera 18 at time t by using formula (d) and formula (e) respectively:

$${x}_{train} ( t ) = {N}_{train} ( t ) \cdot {x}_{w} \qquad ( d )$$

$${x}_{camera} ( t ) = {N}_{camera} ( t ) \cdot {x}_{w} \qquad ( e )$$

where, in formula (d) and formula (e), x_{w} represents a single pulse displacement, x_{w}=πmZ/Nₚ, and N_{camera}(t) is a pulse signal of a rotation angle of the second drive motor at time t;
step 6.8, when x_{camera}(t)≥x_{set,camera}, controlling, by the control cabinet 20, the first drive motor to apply a reverse torque to perform deceleration braking on the train model 1, otherwise, t+1 is assigned to t, and the step 6.2 is returned to execute sequentially;
when x_{camera}(t)≥x_{set,camera}, controlling, by the control cabinet 20, the second drive motor to apply a reverse torque to perform deceleration braking on the motion camera 18, otherwise, t+1 is assigned to t, and the step 6.6 is returned to execute sequentially.
step 7, closing, by the control cabinet 20, the solenoid valve 10, returning the mass flow in the flow meter 12 to be zero, and closing the temperature probe and the high-speed acquisition device 26 and the water-cooled device, when Nₜᵣₐᵢₙ(t)=0 and N_{camera}(t)=0, which means that braking is completed. If the experiment is not terminated, the control cabinet 20 sends a reset command and starts executing step 1. If the experiment is terminated, the control cabinet 20 controls a test bench to power off and generates a comprehensive report including a device running log.

In the present embodiment, a fire characteristic parameter processing method based on high-speed running train in tunnel within long-haul tunnel sections is applied to the above-mentioned control system and is carried out according to following steps:
step I, stabilizing a flame video dynamically:
step 1.1, selecting an identification light area (ROI₁) and its extended area (ROI₂) in a first frame of the video for feature detection and dynamic tracking through an interactive interface;
step 1.2, performing feature detection on the identification light area (ROI₁) selected in the first frame of the video based on an improved Oriented FAST and Rotated BRIEF (ORB) feature point detection algorithm, and outputting a feature point set {p₁, p₂, . . . , pₘ};
step 1.3, tracking the identification light frame by frame through using an optical flow method (Lucas-Kanade optical flow method) in the extended area (ROI₂) based on the feature point set, and calculating rigid motion parameters of the identification light between adjacent video frames (including translation vectors Δx, Δy, and rotation angle θ);
step 1.4, constructing an affine transformation matrix M,

$$M = [ \begin{matrix}cos θ & - sin θ & Δ x \\ sin θ & cos θ & Δ y\end{matrix} ] ,$$

and performing inverse affine transformation compensation on the video frame by frame according to an inverse matrix M⁻¹ of the affine transformation matrix so as to generate a stabilized flame video sequence and eliminate an image jitter caused by high-speed running of a train model.
step II, extracting flame feature parameters:
step 2.1, obtaining a flame video sequence shot by the motion camera 18 after braking is completed, on which stability processing is performed, then converting it from a RGB color space to a grayscale space, so as to use a threshold segmentation algorithm to binarize each frame of a flame image in the grayscale flame video sequence to obtain a binary flame video sequence;
step 2.2, overlaying the binary flame video sequence frame by frame, and counting a frequency of flame occurrence at each pixel point, so as to construct a flame probability density matrix

$$P ( x , y ) = \frac{1}{N} {\sum }_{t = 1}^{N} {M}_{t} ( x , y )$$

at the pixel point (x, y), where Mₜ(x, y) is a binary value at the pixel point (x, y) in a t^{th} frame flame image, and Nis a total number of frames;
step 2.3, mapping, according to a calibration parameter of the motion camera 18, the pixel point (x, y) to the pixel point (Xᵣₑₐₗ,Yᵣₑₐₗ) in an actual physical coordinate system: Xᵣₑₐₗ=α·x·ρ, Yᵣₑₐₗ=α·y·ρ, SO as to construct a flame probability density matrix

$$P ( {X}_{real} , {Y}_{real} ) = \frac{1}{N} {\sum }_{t = 1}^{N} {M}_{t} ( {X}_{real} , {Y}_{real} )$$

at the pixel point (Xᵣₑₐₗ,Yᵣₑₐₗ) in an actual physical coordinate system, where ρ is a pixel resolution of the motion camera 18, and α is a spatial scale factor of the motion camera 18;
step 2.4, extracting a flame boundary based on P (Xᵣₑₐₗ,Yᵣₑₐₗ), and obtaining flame scale data, which includes a flame length L_{f}, and a flame height H_{f}.
step III, analyzing and processing experimental data:
step 3.1, using formula (f) and formula (g) to establish a dimensionless flame length model and a dimensionless flame height model respectively according to the obtained flame scale data (flame length L_{f}, flame height H_{f}):

$$\frac{{L}_{f}}{D} = {f}_{1} ( \text{?} , {V}^{*} ) = {f}_{1} ( \frac{{m}_{set} Δ H}{{ρ}_{a} {c}_{p} {T}_{a} {g}^{1 / 2} {D}^{5 / 2}} , \frac{{v}_{set , train}}{\sqrt{gD}} ) \qquad ( f )$$

$$\frac{{H}_{f}}{D} = {f}_{2} ( \text{?} , {V}^{*} ) = {f}_{2} ( \frac{{m}_{set} Δ H}{{ρ}_{a} {c}_{p} {T}_{a} {g}^{1 / 2} {D}^{5 / 2}} , \frac{{v}_{set , train}}{\sqrt{gD}} ) \qquad ( g )$$

where, in formula (f) and formula (g), Q^{&} is a dimensionless fire source heat release rate, V* is a dimensionless train model running speed, D is a diameter of the fire head, ΔH is a calorific value of the fire source fuel, ρₐ is an initial environment density, cₚ is a constant pressure specific heat capacity, Tₐ is an initial environment temperature, and g is a gravitational acceleration;
step 3.2, drawing a time series graph and calculating an average value of a stable segment based on data collected by the thermocouple 31 and the heat flux meter 30 on the top plate and the bottom plate of the train model 2, so as to use an average value of a thermocouple stable segment as a temperature value t_{f} of the train model 2, and use a product of an average value of a heat flux meter stable segment and a correction coefficient as a heat flux value q_{f} of the train model 2;
step 3.3, performing normalization processing on a temperature value t_{f} and a heat flux value q_{f} according to formula (h) and formula (i) respectively to obtain a normalized temperature value

$${t}_{f}^{*}$$

anu a normalized heat flux value

$${q}_{f}^{*} :$$

$${t}_{f}^{*} = \frac{Δ {t}_{f}}{Δ {t}_{peak}} \qquad ( h )$$

$${q}_{f}^{*} = \frac{{q}_{f} {D}^{2}}{{m}_{set} Δ H} \qquad ( i )$$

where, in formula (h) and formula (i), Δt_{f} represents a temperature rise on the top plate and the bottom plate of the train model 2, Δt_{f}=t_{f}−Tₐ, Δtₚₑₐₖ represents a temperature rise peak on the top plate and the bottom plate of the train model 2, Δtₚₑₐₖ=tₚₑₐₖ−Tₐ, and tₚₑₐₖ is a temperature peak on the top plate and the bottom plate of the train model 2.
step 3.4, establishing a temperature rise peak model on the top plate and the bottom plate of the train model 2 according to formula (j):

$$\frac{Δ {t}_{peak}}{{T}_{a}} = {f}_{3} ( \frac{{v}_{set , train}}{\sqrt{gD}} ) \qquad ( j )$$

where, in formula (j), f₃ is a temperature rise peak relationship;
establishing a temperature distribution prediction model on the top plate and the bottom plate of the train model 2 according to formula (k):

$${t}_{f}^{*} = \frac{Δ {t}_{f}}{Δ {t}_{peak}} = {f}_{4} ( \frac{x}{X} ) \qquad ( k )$$

where, in formula (k), f₄ is a temperature distribution relationship, x is a distance between a thermocouple position and the temperature rise peak on the top plate and the bottom plate of the train model 2, X is a characteristic scale of the fire source, and

$$X = {( \frac{{m}_{set} Δ H}{{ρ}_{a} {c}_{p} {T}_{a} {g}^{1 / 2}} )}^{2 / 5} ;$$

step 3.5, obtaining a heat flux distribution characterization model on a roof of a running train on fire according to formula (1):

$${q}_{f}^{*} = \frac{{q}_{f} {D}^{2}}{{m}_{set} Δ H} = {f}_{5} ( \frac{{x}^{′}}{D} , \frac{{v}_{set , train}}{\sqrt{gD}} ) \qquad ( l )$$

where, in formula (1), f₅ is a heat flux distribution relationship, x′ is a distance between the heat flux meter and a center of the fire head on the train model.

Embodiment 1 is a simulation of train roof fire, where,
dismantling a top plate of a train model, and fixing a fire head on the top plate of the train model through bolt connection and aligning with the top plate of the train model, where an outlet direction of the fire head faces a top plate of a tunnel model;
installing a high-frequency acquisition system, arranging a thermocouple, a heat flux meter, etc. on the top plate of the train model, and fixing the high-speed acquisition device and a water-cooled device in a compartment of the train model;
connecting the fire head with a gas supply pipeline, installing the top plate of the train model on the train model, and arranging a high-voltage arc igniter and a temperature probe directly above the fire head on the top plate of the train model;
fixing a motion camera on a first camera support plate of an optical dynamic tracking system, and adjusting a height of a threaded connecting rod between the first camera support plate and a second camera support plate so as to adjust a shooting angle of the motion camera;
starting the control cabinet, and preliminarily collecting and debuging the high-frequency acquisition system and the optical dynamic tracking system to ensure that the two systems can effectively collect data;
controlling, by the control cabinet, the train model to move towards a direction of a first locator and the motion camera to move in a direction of a second locator, so as to reset the train model and the motion camera;
initiating a gas cylinder valve and an identification light of the train model when the train model and the motion camera are reset, and then, setting, by the control cabinet, a length of the tunnel model, a length of an optical dynamic tracking system bracket, a mass flow of gas in a flow meter, a running speed of the train model and the motion camera, and a running displacement of the train model and the motion camera;
initiating, by the control cabinet, a solenoid valve, and adjusting a mass flow of gas introduced by the flow meter to a set value, and at the same time, triggering a high-voltage arc igniter to start igniting a fire source;
controlling, by the control cabinet, the train model and the motion camera to run synchronously according to the set parameters after the mass flow of the gas introduced by the flow meter is stable, and starting braking and stopping after the train model and the motion camera run to a set running displacement of the train model and the motion camera;
closing, by the control cabinet, the solenoid valve to stop fuel gas supply at the fire head, where the fire source is extinguished at this time, and then adjusting and setting the mass flow rate of the gas introduced by the flow meter to 0 to close gas supply of the gas supply pipeline immediately, and closing the temperature probe, the high-speed acquisition device, and the water-cooled device;
waiting for a temperature of an experimental platform to drop to a lower temperature if an experiment is not over, resetting the train model and the motion camera, and repeating subsequent operations to carry out experiments under other working conditions;
closing the control cabinet, the identification light and gas cylinder valve, etc. of the train model if the experiment is over.

Embodiment 2 is a simulation of train underbody fire, where,
dismantling a top plate of a train model, fixing a fire head on a bottom plate of the train model through bolt connection and aligning with the bottom plate of the train model, where an outlet direction of the fire head faces a bottom plate of a tunnel model;
connecting the fire head with the gas supply pipeline and arranging a high-voltage arc igniter and a temperature probe directly below the fire head;
installing a high-frequency acquisition system, arranging a thermocouple, a heat flux meter, etc. on the bottom plate of the train model, and fixing the high-speed acquisition device and a water-cooled device in a compartment of the train model;
installing the top plate of the train model on the train model to seal the train model;
fixing a motion camera on a first camera support plate of an optical dynamic tracking system, and adjusting a height of a threaded connecting rod between the first camera support plate and a second camera support plate so as to adjust a shooting angle of the motion camera;
controlling, by the control cabinet, the train model to move towards a direction of a first locator and the motion camera to move in a direction of a second locator, so as to reset the train model and the motion camera;
initiating a gas cylinder valve and an identification light of the train model when the train model and the motion camera are reset, and then, setting, by the control cabinet, a length of the tunnel model, a length of an optical dynamic tracking system bracket, a mass flow of gas in a flow meter, a running speed of the train model and the motion camera, and a running displacement of the train model and the motion camera;
initiating, by the control cabinet, a solenoid valve, and adjusting a mass flow of gas introduced by the flow meter to a set value, and at the same time, triggering a high-voltage arc igniter to start igniting a fire source;
controlling, by the control cabinet, the train model and the motion camera to run synchronously according to the set parameters after the mass flow of the gas introduced by the flow meter is stable, and starting braking and stopping after the train model and the motion camera run to a set running displacement of the train model and the motion camera;
closing, by the control cabinet, the solenoid valve to stop fuel gas supply at the fire head, where the fire source is extinguished at this time, and then adjusting and setting the mass flow rate of the gas introduced by the flow meter to 0 to close gas supply of the gas supply pipeline immediately, and closing the temperature probe, the high-speed acquisition device, and the water-cooled device;
waiting for a temperature of an experimental platform to drop to a lower temperature if an experiment is not over, resetting the train model and the motion camera, and repeating subsequent operations to carry out experiments under other working conditions;
closing the control cabinet, the identification light and gas cylinder valve, etc. of the train model if the experiment is over.

Compared with the prior art, the beneficial effects of the present disclosure are as follows.
1. The present disclosure proposes an experimental platform for dynamic fire holographic simulation and intelligent measurement and control for high-speed running train in tunnel, which integrates multiple functional modules, such as the control cabinet, the high-frequency acquisition system, the optical dynamic tracking system, the multi-modal fire holographic simulation system, etc., and can achieve efficient collaborative work between the various parts according to the control steps, and realize effective research on the fire characteristics of the high-speed running train.
2. The tank chain in the present disclosure is provided with the power bus, the control bus, and the gas supply pipeline, which can provide stable power supply, signal transmission and gas delivery for multiple components in the system platform (such as the drive motor, the solenoid valve, the fire head, etc.), so as to avoid problems, such as the entanglement interference, the fuel leakage, etc., which are caused by previous design methods in complex operating environments, thereby improving the stability and the durability of the system.
3. The design of the fire head in the present disclosure enables it to accurately simulate different fire scales by adjusting the gas flow rate, and can simulate different fire scenarios (train roof fire, compartment fire, and train underbody fire) by adjusting the fixed position with the train model, and at the same time, the design of the fire head in the fire source system can effectively prevent the fire source from being extinguished during high-speed running, which is convenient for decoupling research on the fire combustion characteristics of the train under high-speed running.
4. The system of the present disclosure adopts transmission methods such as the gear and the sliding bearing. The driving motor can enable the train model and the motion camera to move smoothly and accurately in the tunnel through the meshing transmission method of the gear and the rack. This approach eliminates the vibration and instability inherent in traditional direct motor drives, guaranteeing synchronized, stable running of the train model and motion camera over long-haul tunnel sections.
5. The experimental platform for high-speed running train in tunnel features dual parallel tracks enabling synchronized movement of the train model and motion camera. This configuration achieves precise flame form capture during high-speed running. Coupled with identification lights on the train model and proprietary flame video analysis algorithms, the system delivers stabilized footage critical for comprehensive fire characteristic analysis.
6. The workflow of the system of the present disclosure tends to be automated, the control cabinet, as the core control unit of the entire fire simulation system, can be operated through the panel. The safety, the convenience and the repeatability of the experimental process are improved through the precise motion control, the delayed start mechanism, the solenoid valve safety protection, etc. of the control cabinet.

To the claims:

1. An experimental platform for dynamic fire holographic simulation and intelligent measurement and control for high-speed running train in tunnel, comprising: a tunnel model, a train model, a high-speed meshing drive system, a multi-modal fire holographic simulation system, an optical dynamic tracking system, a high-frequency acquisition system, and a control cabinet;
a bottom plate of the tunnel model is integrated with a sliding rod and a rack, so as to provide a rail of the train model, wherein the train model runs on the rail through the high-speed meshing drive system;
the multi-modal fire holographic simulation system is used to simulate fires at different fire locations of the train model;
the optical dynamic tracking system runs synchronously with the train model and is used to capture a flame dynamic form of the train model in real time;
the high-frequency acquisition system is used to record parameters comprising a temperature, a heat flux, and a gas concentration in real time; and
the control cabinet is used to control running of the train model and the optical dynamic tracking system, fire extent of the multi-modal fire holographic simulation system, shooting duration of the optical dynamic tracking system, and start and stop of the high-frequency acquisition system.

2. The experimental platform for dynamic fire holographic simulation and intelligent measurement and control for high-speed running train in tunnel according to claim 1, wherein the tunnel model and the train model are arranged as follows:
the tunnel model is fixed on a tunnel model bracket, wherein a top plate of the tunnel model bracket serves as the bottom plate of the tunnel model, the tunnel model is spliced by a plurality of standard section models, any one of the plurality of standard section models is a door-shaped model composed of three aluminum alloy plates, a high-temperature resistant fireproof board is provided inside the aluminum alloy plates, and a high-temperature resistant glass is provided on side of any one of the aluminum alloy plates;
a slot is installed on an outer side of the top plate of the tunnel model bracket, wherein two sliding rods are fixed at a center of the top plate, the rack is laid on an inner side of the top plate, two tunnel model stoppers are installed at both ends of the top plate of the tunnel model bracket, and the top plate of the tunnel model bracket is provided with a first locator on a running start side of the train model;
the train model is divided into a straight segment body and an arc segment head, wherein the train model is spliced by the aluminum alloy plates, the train model is fixed on a support plate of the train model by two support rods, a bottom of the support plate of the train model is installed with a first sliding bearing, the first sliding bearing is arranged on two sliding rods on the top plate of the tunnel model bracket, and the arc segment head of the train model is provided with an identification light powered by battery.

3. The experimental platform for dynamic fire holographic simulation and intelligent measurement and control for high-speed running train in tunnel according to claim 2, wherein the high-speed meshing drive system comprises: a first gear, a first drive motor, a first motor support frame, a first connecting plate, a first power line, a first control line, and a first tank chain;
the first motor support frame is assembled by the three aluminum alloy plates, wherein the first drive motor is arranged on an inner bottom surface of the first motor support frame, the first drive motor is connected to a first gear through a gear shaft, and the first gear is meshed with a rack on the top plate of the tunnel model bracket;
a bottom of a bottom surface of the first motor support frame is connected to a second sliding bearing, wherein the second sliding bearing is arranged on the two sliding rods of the top plate of the tunnel model bracket and is located behind a running direction of the first sliding bearing;
a side of the first motor support frame with same direction as a running direction of the train model is connected to the support plate of the train model through a first connecting plate, whereby the first drive motor drives the train model to run in a sliding way on the two sliding rods through the first sliding bearing and the second sliding bearing; and
a side of the first motor support frame with opposite direction to a running direction of the train model is connected to the first tank chain, wherein the first tank chain is arranged in the slot of the top plate of the tunnel model bracket, and the first power line and first control line are arranged inside the first tank chain and connected to the control cabinet, so as to provide power and control signal for the first drive motor.

4. The experimental platform for dynamic fire holographic simulation and intelligent measurement and control for high-speed running train in tunnel according to claim 3, wherein the multi-modal fire holographic simulation system comprises: a fire head, a solenoid valve, a solenoid valve power cord, a flow meter, a first gas supply pipeline, a second gas supply pipeline, a third gas supply pipeline, a gas cylinder, a high-voltage arc igniter, and a temperature probe;
the fire head comprises: an inner gas supply component and an outer sleeve, wherein the inner gas supply component comprises: a gas supply head and a pneumatic joint;
the gas supply head is provided with a gas supply passage with air holes therein, wherein both ends of the gas supply head are respectively connected with the pneumatic joint and the outer sleeve in a threaded way, and there is an annular gap between the gas supply head and the outer sleeve for outer gas supply;
the fire head is fixed on the train model through a threaded connection, wherein the high-voltage arc igniter and the temperature probe are arranged directly above the fire head, the gas cylinder is connected to the third gas supply pipeline through a pressure reducing valve, the third gas supply pipeline is connected to an inlet of the flow meter, an outlet of the flow meter is connected to the second gas supply pipeline, the second gas supply pipeline is arranged inside the first tank chain and connected to the solenoid valve, the solenoid valve is connected to the first gas supply pipeline, and the first gas supply pipeline is connected to the pneumatic joint of the fire head;
the flow meter controls a power of a fire source by adjusting a mass flow of gas being introduced.

5. The experimental platform for dynamic fire holographic simulation and intelligent measurement and control for high-speed running train in tunnel according to claim 4, wherein the optical dynamic tracking system comprises: an optical dynamic tracking system bracket, a motion camera, a first camera support plate, a second camera support plate, a synchronous tracking power system, two optical dynamic tracking system stoppers, and a second locator;
a slot is installed on an outer side of a top plate of the optical dynamic tracking system bracket, wherein two sliding rods are fixed at a center of the top plate, a rack is laid on an inner side of the top plate, two optical dynamic tracking system stoppers are installed at both ends of the top plate of the optical dynamic tracking system bracket, and the top plate of the optical dynamic tracking system bracket is provided with a second locator on a running start side of the motion camera;
the motion camera is fixed on the first camera support plate, wherein the first camera support plate is connected to the second camera support plate through two threaded connecting rods, a third sliding bearing is installed at a bottom of the second camera support plate, and the third sliding bearing is arranged on the two sliding rods of the top plate of the optical dynamic tracking system bracket.

6. The experimental platform for dynamic fire holographic simulation and intelligent measurement and control for high-speed running train in tunnel according to claim 5, wherein the synchronous tracking power system comprises: a second gear, a second drive motor, a second motor support frame, a second connecting plate, a second power line, a second control line, and a second tank chain;
the second motor support frame is an aluminum alloy flat plate, wherein the second drive motor is arranged on an inner bottom surface of the second motor support frame, the second drive motor is connected to the second gear through a gear shaft, and the second gear is meshed with a rack on the optical dynamic tracking system bracket;
a bottom of a bottom surface of the second motor support frame is connected to a fourth sliding bearing, and the fourth sliding bearing is arranged on the two sliding rods of the top plate of the optical dynamic tracking system bracket and is located behind a running direction of the third sliding bearing;
a side of the second motor support frame with same direction as a running direction of the motion camera is connected to the second camera support plate of the motion camera through the second connecting plate, whereby the second drive motor drives the motion camera to run in a sliding way on the two sliding rods through the third sliding bearing and the fourth sliding bearing; and
a side of the second motor support frame with opposite direction to a running direction of the motion camera is connected to the second tank chain, wherein the second tank chain is arranged in the slot of the top plate of the optical dynamic tracking system bracket, and the second power line and the second control line are arranged inside the second tank chain and connected to the control cabinet, so as to provide power and control signal for the second drive motor.

7. The experimental platform for dynamic fire holographic simulation and intelligent measurement and control for high-speed running train in tunnel according to claim 6, wherein the high-frequency acquisition system comprises: a thermocouple, a heat flux meter, a high-speed acquisition device, and water-cooled device, wherein the water-cooled device comprises: a water pump, a water tank, and a water pump power line;
the thermocouple and the heat flux meter are arranged on a top plate and a bottom plate of the train model, wherein a wiring of the thermocouple and the heat flux meter is connected to the high-speed acquisition device, the water pump is fixed to a bottom of the water tank, a water inlet pipe of the heat flux meter is connected to a water outlet pipe of the water pump, a water outlet pipe of the heat flux meter is inserted into the water tank, the second power line provides a power for the water pump, and the high-speed acquisition device is powered by using a battery.

8. A control system based on the experimental platform for dynamic fire holographic simulation and intelligent measurement and control for high-speed running train in tunnel according to claim 7, configured to carry out following steps:
step 1, controlling, by the control cabinet, the first drive motor to drive the train model to move toward a direction of the first locator in a low-speed mode, and controlling the second drive motor to drive the motion camera to move toward a direction of the second locator in the low-speed mode;
when the train model reaches the first locator, and a Hall sensor in the first locator detects a change in a magnetic field, an encoder pulse count value of the first drive motor is cleared, and a position of the train model when it reaches the first locator is set to an initial position x_{0,train};
when the motion camera reaches the second locator, and a Hall sensor in the second locator detects a change in a magnetic field, an encoder pulse count value of the second drive motor is cleared, and a position of the motion camera when it reaches the second locator is set to an initial position x_{0,camera};
step 2, setting experimental parameters, comprising: a length of the tunnel model Lₜᵤₙₙₑₗ, a length of the optical dynamic tracking system bracket L_{trace}, the mass flow of gas in the flow meter mₛₑₜ, a running speed of the train model v_{set,train}, a running speed of the motion camera v_{set,camera}, a running displacement of the train model x_{set,train}, and a running displacement of the motion camera x_{set,camera};
step 3, starting, by the control cabinet, the solenoid valve, starting the flow meter to supply gas according to a set target mass flow mₛₑₜ, and at the same time, triggering the high-voltage arc igniter to ignite the fire source, and synchronously starting the temperature probe to monitor a state of the fire source in real time;
step 4, collecting, by the flow meter, a mass flow mᵣₑₐₗ(1) at time t in the gas supply pipeline, and calculating a mass flow fluctuation rate e(t)=mₛₑₜ−mᵣₑₐ (t) at time t, wherein if e(t) is less than a set flow threshold, then a step 5 is executed, otherwise, a Proportional Integral Derivative (PID) control algorithm is used to adjust the mᵣₑₐₗ(t), and a flow control value u(t) at time t is obtained by using formula (a), so as to control the flow meter to adjust a mass flow of its own gas being introduced, whereby e(t) is less than the set flow threshold:
$$u ( t ) = {K}_{p} e ( t ) + {K}_{i} {\int }_{0}^{t} e ( τ ) dt + {K}_{d} \frac{de ( t )}{dt} \qquad ( a )$$
wherein, in formula (a), Kₚ is a proportional coefficient, Kᵢ is an integral coefficient, and K_{d} is a differential coefficient;
step 5, triggering, by the control cabinet, the high-voltage arc igniter to ignite the fire source, and synchronously starting the temperature probe to monitor the state of the fire source in real time, and starting the high-speed acquisition device to collect data from the thermocouple and the heat flux meter;
step 6, controlling the train model and the motion camera to run synchronously;
step 7, closing, by the control cabinet, the solenoid valve, returning the mass flow in the flow meter to be zero, and closing the temperature probe and the high-speed acquisition device and the water-cooled device, when Nₜᵣₐᵢₙ(t)=0 and N_{camera}(t)=0, which means that braking is completed.

9. The control system according to claim 8, wherein the step 6 further comprises:
step 6.1, obtaining a control frequency fₜᵣₐᵢₙ of the first drive motor according to formula (b) to control the train model to run at the running speed v_{set,train}:
$${f}_{train} = \frac{{v}_{set , train} \cdot {N}_{p}}{π mZ} \qquad ( b )$$
wherein, in formula (b), m is a module of a gear in the train model, Z is a teeth number of the gear in the train model, and Nₚ is a number of pole pairs of the first drive motor;
step 6.2, using, by the control cabinet, a high-precision encoder built in the first drive motor to collect a pulse signal Nₜᵣₐᵢₙ(t) of a rotation angle of the first drive motor at time t, so as to use formula (c) to obtain a running speed v_{real,train}(t) of the train model at time t:
$${v}_{real , train} ( t ) = \frac{N ( t ) \cdot Δθ \cdot π mZ}{60 {N}_{p}} \qquad ( c )$$
wherein, in formula (c), Δθ is a fixed angle of a rotation of a motor gear corresponding to a single pulse;
step 6.3, calculating, by the control cabinet, a running speed error v_{e,train}(t)=v_{set,train}−v_{real,train}(t) of the train model at time t;
step 6.4, if the v_{e,train}(t) is less than a set speed threshold, then the step 5 is executed, otherwise, the PID control algorithm is used to adjust the v_{e,train}(t) to obtain a control frequency f_{output,train}(t) of the first drive motor at time t, so as to control the running speed v_{e,train}(t) of the train model at time t to be less than the set speed threshold;
step 6.5, if L_{trace}<Lₜᵤₙₙₑₗ, calculating, by the control cabinet, a delayed start time t_{delay}=(Lₜᵤₙₙₑₗ−L_{trace})/vₜᵣₐᵢₙ of the motion camera, otherwise, t_{delay}=0 is set to start the motion camera according to the t_{delay};
step 6.6, calculating, by the control cabinet, a running speed v_{e,camera}(t)=v_{set,camera}−v_{real,camera}(t) of the motion camera at time t, wherein if v_{e,camera}(t) is less than a set speed threshold, then step 6.7 is executed, otherwise, adjusting v_{e,camera}(t) according to the PID control algorithm to control v_{e,camera}(t) to be less than the set speed threshold;
step 6.7, calculating, by the control cabinet, an actual displacement xₜᵣₐᵢₙ(t) of the train model at time t and an actual displacement x_{camera}(t) of the motion camera at time t by using formula (d) and formula (e) respectively:
$${x}_{train} ( t ) = {N}_{train} ( t ) \cdot {x}_{w} \qquad ( d )$$
$${x}_{camera} ( t ) = {N}_{camera} ( t ) \cdot {x}_{w} \qquad ( e )$$
wherein, in formula (d) and formula (e), x_{w} represents a single pulse displacement, x_{w}=πmZ/Nₚ, and N_{camera}(t) is a pulse signal of a rotation angle of the second drive motor at time t;
step 6.8, when x_{camera}(t)>x_{set,camera}, controlling, by the control cabinet, the first drive motor to apply a reverse torque to perform deceleration braking on the train model, otherwise, t+1 is assigned to t, and the step 6.2 is returned to execute sequentially;
when x_{camera}(t)≥x_{set,camera}, controlling, by the control cabinet, the second drive motor to apply a reverse torque to perform deceleration braking on the motion camera, otherwise, t+1 is assigned to t, and the step 6.6 is returned to execute sequentially.

10. A fire characteristic parameter processing method based on the control system according to claim 8, comprising following steps:
step I, obtaining a flame video sequence shot by the motion camera after braking is completed, on which stability processing is performed, then converting it from a Red Green Blue (RGB) color space to a grayscale space, so as to use a threshold segmentation algorithm to binarize each frame of a flame image in the grayscale flame video sequence to obtain a binary flame video sequence;
step II, overlaying the binary flame video sequence frame by frame, and counting a frequency of flame occurrence at each pixel point, so as to construct a flame probability density matrix
$$P ( x , y ) = \frac{1}{N} {\sum }_{t = 1}^{N} {M}_{t} ( x , y )$$
at the pixel point (x, y), wherein Mₜ(x, y) is a binary value at the pixel point (x, y) in a t^{th} frame flame image, and N is a total number of frames;
step III, mapping, according to a calibration parameter of the motion camera, the pixel point (x, y) to the pixel point (Xᵣₑₐₗ,Yᵣₑₐₗ) in an actual physical coordinate system: Xᵣₑₐₗ=α·x·ρ, Yᵣₑₐₗ=α·y·ρ, so as to construct a flame probability density matrix
$$P ( {X}_{real} , {Y}_{real} ) = \frac{1}{N} {\sum }_{t = 1}^{N} {M}_{t} ( {X}_{real} , {Y}_{real} )$$
at the pixel point (Xᵣₑₐₗ,Yᵣₑₐₗ) in an actual physical coordinate system, wherein p is a pixel resolution of the motion camera, and a is a spatial scale factor of the motion camera;
step Iv, extracting a flame boundary based on P (Xᵣₑₐₗ,Yᵣₑₐₗ), and obtaining flame scale data, which comprises a flame length L_{f}, and a flame height H_{f},
step V: using formula (f) and formula (g) to establish a dimensionless flame length model and a dimensionless flame height model respectively:
$$\frac{{L}_{f}}{D} = {f}_{1} ( {\dot{Q}}^{*} , {V}^{*} ) = {f}_{1} ( \frac{{m}_{set} Δ H}{{ρ}_{a} {c}_{p} {T}_{a} {g}^{1 / 2} {D}^{5 / 2}} , \frac{{v}_{set , train}}{\sqrt{gD}} ) \qquad ( f )$$
$$\frac{{H}_{f}}{D} = {f}_{2} ( {\dot{Q}}^{*} , {V}^{*} ) = {f}_{2} ( \frac{{m}_{set} Δ H}{{ρ}_{a} {c}_{p} {T}_{a} {g}^{1 / 2} {D}^{5 / 2}} , \frac{{v}_{set , train}}{\sqrt{gD}} ) \qquad ( g )$$
wherein, in formula (f) and formula (g),
$$\underline{{\dot{Q}}^{*}} [ [ \text{?} ] ]$$
is a dimensionless heat release rate of the fire source, v* is a dimensionless running speed of the train model, D is a diameter of the fire head, ΔH is a calorific value of fire source fuel, ρₐ is an initial environment density, cₚ is a constant pressure specific heat capacity, Tₐ is an initial environment temperature, g is a gravitational acceleration, f₁ is a flame length relationship, and f₂ is a flame height relationship;
step VI, drawing a time series graph and calculating an average value of a stable segment based on data collected by the thermocouple and the heat flux meter on the top plate and the bottom plate of the train model, so as to use an average value of a thermocouple stable segment as a temperature value t_{f} of the train model, and use a product of an average value of a heat flux meter stable segment and a correction coefficient as a heat flux value q_{f} of the train model;
step VII, performing normalization processing on a temperature value t_{f} and a heat flux value q_{f} according to formula (h) and formula (i) respectively to obtain a normalized temperature value
$${t}_{f}^{*}$$
and a normalized heat flux value
$${q}_{f}^{*} :$$
$${t}_{f}^{*} = \frac{Δ {t}_{f}}{Δ {t}_{peak}} \qquad ( h )$$
$${q}_{f}^{*} = \frac{{q}_{f} {D}^{2}}{{m}_{set} Δ H} \qquad ( i )$$
wherein, in formula (h) and formula (i), Δt_{f} represents a temperature rise on the top plate and the bottom plate of the train model, Δt_{f}=t_{f}−Tₐ, Δtₚₑₐₖ represents a temperature rise peak on the top plate and the bottom plate of the train model, Δtₚₑₐₖ=tₚₑₐₖ−Tₐ, and tₚₑₐₖ is a temperature peak on the top plate and the bottom plate of the train model;
step VIII, establishing a temperature rise peak model on the top plate and the bottom plate of the train model according to formula (j):
$$\frac{Δ {t}_{peak}}{{T}_{a}} = {f}_{3} ( \frac{{v}_{set , train}}{\sqrt{gD}} ) \qquad ( j )$$
wherein, in formula (j), f₃ is a temperature rise peak relationship;
establishing a temperature distribution prediction model on the top plate and the bottom plate of the train model according to formula (k):
$${t}_{f}^{*} = \frac{Δ {t}_{f}}{Δ {t}_{peak}} = {f}_{4} ( \frac{x}{X} ) \qquad ( k )$$
wherein, in formula (k), f₄ is a temperature distribution relationship, x is a distance between a thermocouple position and the temperature rise peak on the top plate and the bottom plate of the train model, X is a characteristic scale of the fire source, and
$$X = {( \frac{{m}_{set} Δ H}{{ρ}_{a} {c}_{p} {T}_{a} {g}^{1 / 2}} )}^{2 / 5} ;$$
step IX, obtaining a heat flux distribution characterization model on a roof of a running train on fire according to formula (1):
$${q}_{f}^{*} = \frac{{q}_{f} {D}^{2}}{{m}_{set} Δ H} = {f}_{5} ( \frac{{x}^{′}}{D} , \frac{{v}_{set , train}}{\sqrt{gD}} ) \qquad ( l )$$
wherein, in formula (1), f₅ is a heat flux distribution relationship, x′ is a distance between the heat flux meter and a center of the fire head on the train model.
